(19) United States
(12) Patent Application Publication
(10) Pub. No.: US 2023/0290639 A1
(43) Pub. Date: Sep. 14, 2023

(54) LOW RESISTANCE GATE OXIDE METALLIZATION LINER

(71) Applicant: Lam Research Corporation, Fremont, CA (US)

(72) Inventors: Lawrence Schloss, Palo Alto, CA (US); Anand Chandrashekar, Fremont, CA (US); Juwen Gao, San Jose, CA (US); Stephanie Noelle Sandra Sawant-Goubert, San Jose, CA (US); Yu Pan, San Jose, CA (US)

(21) Appl. No.: 18/003,137

(22) PCT Filed: Jul. 29, 2020
(86) PCT No.: PCT/US2020/070325

§ 371 Date: Dec. 22, 2022

(51) Int. Cl. H01L 21/28; C23C 16/34; C23C 16/14; C23C 16/56; C23C 16/458; C23C 16/455; C23C 16/04

(52) U.S. Cl. CPC H01L 21/28088; H01L 29/4011; C23C 16/34; C23C 16/14; C23C 16/56; C23C 16/4583; C23C 16/45565; C23C 16/45527; C23C 16/045

(57) ABSTRACT

Methods and apparatuses for forming low resistivity tungsten using tungsten nitride barrier layers are provided herein. Methods involve depositing extremely thin tungsten nitride barrier layers prior to depositing tungsten nucleation and bulk tungsten layers. Methods are applicable for fabricating tungsten word lines in 3D NAND fabrication as well as for fabricating tungsten-containing components of DRAM and logic fabrication. Apparatus included processing stations with multiple charge volumes to pressurize gases in close vicinity to a showerhead of a processing chamber for processing semiconductor substrates.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Metal film deposition such as tungsten film deposition using chemical vapor deposition techniques is a part of semiconductor fabrication processes. Tungsten films may be used as low resistivity electrical connections in the form of horizontal interconnects, vias between adjacent metal layers, and contacts between a first metal layer and the devices on a silicon substrate. Tungsten films may also be used to form tungsten word lines in 3D NAND applications. In some tungsten deposition processes, a titanium nitride barrier layer is deposited on a dielectric substrate, followed by deposition of a nucleation or seed layer of tungsten film. Thereafter, the remainder of the tungsten film is deposited on the nucleation layer as a bulk layer. The tungsten bulk layer may be formed by the reduction of tungsten hexafluoride (WF₆) with hydrogen (H₂) in a chemical vapor deposition (CVD) process.

As semiconductor devices scale to smaller and smaller technology nodes, shrinking contact and via dimensions make CVD of tungsten more challenging. In 3D NAND fabrication, it is challenging to evenly deposit tungsten into small spaces between oxide surfaces in a staircase structure as diffusion of deposition reactants involves both vertical and lateral diffusion. Increasing aspect ratios can lead to voids or large seams within device features, resulting in lower yields and decreased performance in microprocessor and memory chips. Void-free fill in high aspect ratio features of 10:1, 20:1, or greater is difficult using some CVD tungsten deposition techniques.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided herein are methods of processing semiconductor substrates. One aspect is a method of processing semiconductor substrates, the method including: providing a semiconductor substrate; depositing a tungsten nitride layer on the semiconductor substrate, the tungsten nitride layer having a thickness less than about 30 Å; depositing a tungsten nucleation layer over the tungsten nitride layer; and depositing bulk tungsten over the tungsten nucleation layer and the tungsten nitride layer.

In various embodiments, the tungsten nucleation layer and the bulk tungsten are deposited over the tungsten nitride layer without annealing the tungsten nitride layer. In some embodiments, depositing the tungsten nitride layer further includes annealing the tungsten nitride layer prior to depositing additional tungsten over the tungsten nitride layer. In some embodiments, the thickness of the tungsten nitride layer is between about 20 Å and about 40 Å, and depositing the tungsten nitride layer further includes annealing the tungsten nitride layer prior to depositing additional tungsten over the tungsten nitride layer.

In various embodiments, the depositing the tungsten nitride layer, the depositing the tungsten nucleation layer, and the depositing the bulk tungsten are performed without breaking vacuum. In some embodiments, the depositing the tungsten nitride layer, the depositing the tungsten nucleation layer, and the depositing the bulk tungsten are performed in the same chamber.

In various embodiments, the method also includes annealing the semiconductor substrate at a temperature between about 500° C. and about 800° C. In some embodiments, the semiconductor substrate is annealed after depositing the tungsten nitride layer and before depositing the tungsten nucleation layer. In some embodiments, the semiconductor substrate is annealed after depositing the bulk tungsten. In some embodiments, the temperature is less than a temperature at which tungsten nitride decomposes. In some embodiments, the bulk tungsten is deposited directly on the tungsten nitride layer.

In various embodiments, the tungsten nitride is deposited on a surface of the semiconductor substrate, the surface including oxide. In some embodiments, the oxide is one or more of silicon oxide and aluminum oxide.

In various embodiments, the tungsten nitride is deposited on a partially fabricated semiconductor substrate for forming a 3D NAND structure.

In various embodiments, the tungsten nitride is deposited on a partially fabricated semiconductor substrate for forming a tungsten word line.

One aspect is a method of processing semiconductor substrates, the method including: providing a semiconductor substrate; depositing a tungsten nitride layer on the semiconductor substrate, the tungsten nitride layer having a thickness less than about 30 Å; depositing a tungsten nucleation layer over the tungsten nitride layer; and depositing bulk metal over the tungsten nucleation layer and the tungsten nitride layer.

In various embodiments, the bulk metal is selected from the group consisting of bulk tungsten and bulk molybdenum.

Another aspect involves an apparatus for processing semiconductor substrates, the apparatus including: at least one processing station, the at least one processing station including a process chamber, the process chamber including a showerhead and a pedestal for holding a semiconductor substrate; one or more gas sources; one or more gas inlets configured to deliver gas from the one or more gas sources to one or more corresponding charge volumes; and at least one outlet valve between the one or more corresponding charge volumes and the showerhead for controlling flow of gases from a manifold to the showerhead, whereby a distance between one of the one or more corresponding charge volumes and the showerhead is between about 10 cm and about 60 cm.

In various embodiments, the pedestal is movable between raised and lowered positions.

In various embodiments, the showerhead includes a dual-plenum showerhead.

In various embodiments, the showerhead is heated.

In various embodiments, the one or more corresponding charge volumes are configured to deliver the gas to a manifold.

In various embodiments, the one or more corresponding charge volumes are configured to pressurize gases from the one or more gas sources by closing the at least one outlet valve downstream of the one or more corresponding charge volumes prior to delivering gas to the showerhead.

In various embodiments, the manifold is upstream of the showerhead and downstream of the one or more corresponding charge volumes.

In various embodiments, the apparatus also includes a controller having at least one processor and a memory, such that the at least one processor and the memory are communicatively connected with one another, the at least one processor is at least operatively connected with flow-control hardware, and the memory stores computer-executable instructions for controlling the at least one processor to at least control the flow-control hardware to: cause delivery of a reducing agent from a first of the one or more gas sources to the semiconductor substrate on the pedestal housed in the process chamber; cause delivery of a tungsten-containing precursor from a second of the one of the one or more gas sources to the semiconductor substrate on the pedestal housed in the process chamber; and cause delivery of a nitrogen-containing reactant from a third of the one or more gas sources to the semiconductor substrate on the pedestal housed in the process chamber.

In various embodiments, the third of the one or more gas sources is delivered to the manifold from a line separate from the first of the one or more gas sources and the second of the one or more gas sources.

In various embodiments, the third of the one or more gas sources is delivered through the showerhead through holes in the showerhead separately from the holes in which gases from the first of the one or more gas sources and the second of the one or more gas sources are flowed through the showerhead.

These and other aspects are described further below with reference to the drawings.

### BRIEF DESCRIPTION OF THE DRAWINGS

FIG. 1 is a schematic illustration of a feature filled with tungsten nucleation and bulk layers according to certain disclosed embodiments.

FIG. 2A is a schematic illustration of a side view cross section of an angle of a partially fabricated 3D NAND structure.

FIG. 2B is a schematic illustration of a side view cross section from another angle of a partially fabricated 3D NAND structure.

FIG. 3A is a schematic illustration of a side view cross section of an angle of a partially fabricated 3D NAND structure.

FIG. 3B is a schematic illustration of a side view cross section from another angle of a partially fabricated 3D NAND structure.

FIG. 4 is a process flow diagram for depositing tungsten in accordance with certain disclosed embodiments.

FIG. 5 is a schematic illustration of a process chamber for performing certain disclosed embodiments.

FIG. 6 is a schematic illustration of a gas flow diagram for an apparatus that may be used to perform certain disclosed embodiments.

FIGS. 7 and 8 are schematic illustrations of example processing systems that may be suitable for conducting tungsten deposition processes in accordance with certain disclosed embodiments.

FIG. 9 is a graph of resistivity of films deposited.

FIG. 10 is a graph of stack resistivity of films deposited to a thickness of 200 Å.

FIG. 11 is a graph of stack resistivity of films deposited on tungsten nitride barrier layers of different thicknesses.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processes often involve deposition of tungsten and/or molybdenum materials. Tungsten and molybdenum materials may be deposited to fill features on semiconductor substrates. Such features may be used to form metal contacts, metal lines, or other metal structures. While tungsten is discussed in certain disclosed embodiments, it will be understood that certain disclosed embodiments are also applicable to formation of molybdenum materials.

One technique for depositing metal in features is by chemical vapor deposition (CVD). In some processes, a titanium nitride barrier layer is first deposited into the feature, and a tungsten nucleation layer is deposited over the barrier layer, followed by tungsten bulk deposition over the tungsten nucleation layer. Barrier layers can be used to reduce diffusion of particular atoms from the tungsten film into the adjacent material, such as oxide, and vice versa. In general, tungsten nucleation layers generally have higher resistivity tungsten than bulk tungsten, but since bulk tungsten can grow directly on tungsten nucleation layers in a way that grows lower resistivity tungsten than bulk tungsten can grow directly on a titanium nitride layer, tungsten nucleation layers are deposited to reduce the overall resistivity within a feature.

As devices scale to smaller technology nodes, however, there are various challenges in tungsten fill. A smaller feature may still be filled with a titanium nitride barrier layer and tungsten nucleation layer before bulk tungsten is deposited, resulting in less bulk tungsten deposited and an overall increase in stack resistivity since more of the stack includes titanium nitride barrier and tungsten nucleation layers, both of which have higher resistivity than bulk tungsten.

One challenge is preventing an increase in resistance as thinner films are deposited in contacts and vias due to scattering effects in a thinner tungsten film. As features become smaller, low resistivity tungsten films minimize power losses and overheating in integrated circuit designs. Resistivity of a tungsten film depends on the thickness of the film deposited. For example, a 50 Å tungsten film may have a resistivity of 60 μΩ-cm while a 100 Å film may have a resistivity of 30 μΩ-cm. A thin barrier or tungsten nucleation film previously used to deposit in larger features now deposited into smaller features occupy a larger percentage of the smaller features, thereby reducing the region in which to deposit low resistivity bulk tungsten. As a result, the overall resistivity is higher than that of larger features.

FIG. 1 shows a volume occupied by a nucleation film 110 and a bulk tungsten material 120 in a via or contact structure 100. Because the resistivity of the nucleation layer is higher than that of the bulk layer (ρ_{nucleation}>ρ_{bulk}), reducing the total resistance to keep the resistance as low as possible involves minimizing the thickness of the nucleation layer. On the other hand, the tungsten nucleation layer should be sufficiently thick to fully cover the underlying substrate to support high quality bulk deposition growth on the tungsten nucleation layer due to poor growth properties of bulk tungsten on a titanium nitride barrier layer.

Tungsten nitride is used in some back end of line applications where metal-metal interfaces may form undesirable alloys. For example, tungsten nitride may be placed between an aluminum and copper material to prevent an alloy from forming at an aluminum-copper interface. While tungsten nitride is used in some back end of line applications, tungsten nitride has not been as widely used for gate oxide contact applications, and in particular for 3D NAND fabrication because it is difficult to diffuse the deposition chemistry for depositing tungsten nitride into complex 3D structures both vertically and laterally to result in uniform deposition.

Provided herein are methods of using tungsten nitride as a metallization liner in gate oxide applications. In gate oxide applications, using tungsten nitride in lieu of titanium nitride has an advantage of reducing the overall resistivity by providing a tungsten-containing surface upon which tungsten can nucleate while still providing good barrier properties. Certain disclosed embodiments involve depositing extremely thin layers of tungsten nitride, such as less than about 30 Å, or between about 10 Å to about 15 Å, prior to depositing tungsten nucleation layers and bulk tungsten to further reduce the resistivity. Deposition of titanium nitride at such thin thicknesses cannot achieve barrier properties and resistivity as low as for tungsten nitride. Certain disclosed embodiments also include annealing the substrate to convert a particular depth of the barrier layer to tungsten metal, which may be performed prior to or after deposition of tungsten nucleation and/or bulk tungsten layers. Annealing may be performed at least about 650° C. or greater temperatures.

Certain disclosed embodiments are particularly useful for reducing resistivity in tungsten deposited for memory applications, such as for fabrication of MRAM devices. Certain methods described herein involve annealing a thick tungsten nitride barrier layer prior to depositing a tungsten nucleation layer and tungsten bulk layer to modify at least some of the exposed tungsten nitride barrier layer depth to convert it to tungsten and depositing tungsten nucleation layer and tungsten bulk layer on the annealed thick tungsten nitride barrier layer. Certain embodiments involve depositing a thin tungsten nitride layer and modulating the thickness of deposited tungsten nucleation layer and depositing a tungsten bulk layer to reduce total resistance of tungsten in a feature.

In general, tungsten nitride is more conductive than titanium nitride. Titanium nitride may not have sufficient step coverage on an oxide surface, leading to inconsistent tungsten growth which results in a rough film with voids, and also leading to poor diffusion barrier properties, thereby allowing boron and fluorine atoms to diffuse into the oxide. However, simply replacing titanium nitride with tungsten nitride may not be sufficient to improve the overall stack resistance. Stack resistance may be defined as the resistance of a particular thickness of a stack of films including the barrier layer, nucleation layer, and bulk layer. Tungsten nitride is more resistive than a tungsten nucleation layer which is more resistive than bulk tungsten. Thus, tungsten nitride as a barrier layer may exhibit properties similar to that of an insulator because the bulk tungsten and tungsten nucleation layers are both more conductive. As a result, most of the conductive properties may lie within the bulk tungsten layer. Extremely thin tungsten nitride barrier layers may achieve particularly surprising and good results for reducing overall stack resistivity in some applications.

Tungsten nitride may be used for at least two applications. In one application, tungsten nitride is deposited and then annealed to remove nitrogen from the tungsten nitride, thereby resulting in a tungsten nitride layer that includes mostly tungsten—that is, atomically, the material includes majority tungsten atoms—such that a stack including this annealed tungsten nitride layer having a thickness of about 10% to about 15% of the stack (with the remaining being tungsten nucleation layer and bulk tungsten) has a reduced resistivity of about 10% to about 15% relative to a tungsten nitride layer that is not annealed.

In a second application, if tungsten nitride is used as a barrier layer, a thinner tungsten nitride layer is used before depositing a tungsten nucleation layer, thereby allowing more low resistivity bulk tungsten to be deposited. Additionally, if tungsten nitride is used as a barrier layer, a thinner tungsten nucleation layer may be used before depositing low resistivity bulk tungsten. That is, in a stack where a tungsten nucleation layer is formed on titanium nitride, a minimum thickness of tungsten nucleation layer (such as about 20 Å to about 25 Å) is used to ensure bulk tungsten is grown in to yield grains that have an overall lower resistance. However, a thicker tungsten nucleation layer results in reduced bulk tungsten thickness that can be deposited inside a structure of fixed size. When titanium nitride is replaced with tungsten nitride, however, the tungsten nucleation layer can be reduced in thickness (such as about 12 Å) and bulk tungsten may be deposited for the remaining thickness, thereby improving the resistivity reduction by about 8% for a 200 Å film. A reduced tungsten nitride layer may also be used to reduce resistivity; that is, a thickness of less than about 30 Å or between about 10 Å and about 15 Å of tungsten nitride barrier layer may be used in conjunction with a thin tungsten nucleation layer to achieve even lower resistivity. Further, combining such operations with particular bulk tungsten deposition processes, such as depositing using a combination of tungsten hexafluoride and nitrogen gas, can achieve even further reduced stack resistivity of up to 40% or up to 70% reduction compared to stacks deposited using titanium nitride barrier layers, tungsten nucleation layers, and bulk tungsten deposited using tungsten hexafluoride and co-flowed nitrogen/hydrogen gases.

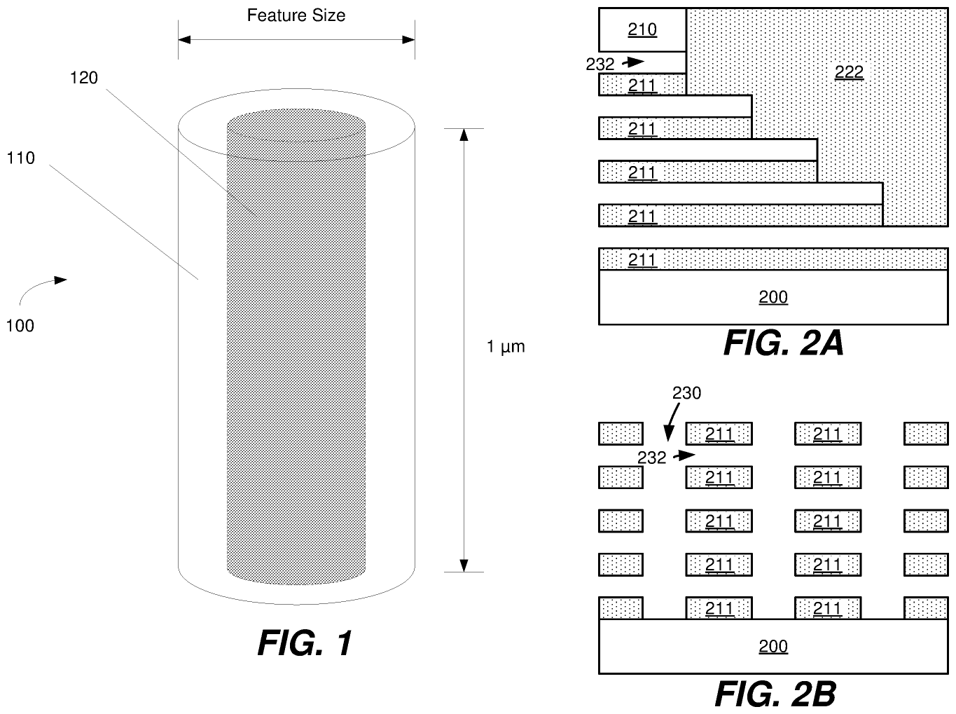

Certain disclosed embodiments may be particularly suitable for depositing tungsten word lines in 3D NAND fabrication. FIGS. 2A and 2B show a partially fabricated 3D NAND structure from two different angles. FIG. 2A shows a substrate 200 with layers of oxide 211 and overlying oxide 222 optionally deposited thereon, after nitride layer is removed from between the layers of oxide 211, with a mask 210 over the top of the staircase structure. Oxide 211 and/or oxide 222 may be silicon oxide or aluminum oxide in some embodiments. In some embodiments, the oxide layers and the space between the oxide layers may be about the same thickness, such as about 10 nm and about 100 nm, or about 350 Å in some embodiments. The staircase structure shown in FIG. 2A may be fabricated using patterning processes after depositing alternating layers of oxide and nitride (an “ONON” stack). Although only a few “steps” of a staircase are shown, it will be understood that a staircase pattern includes between 24 and 256 steps. The staircase pattern may be formed using a variety of patterning techniques. For example, one technique may include depositing a sacrificial layer over the substrate and masking regions of the substrate to etch each set of oxide and nitride layers to form the staircase.

Oxide 222 may be the same composition as the oxide 211 deposited in layers of the ONON stack. In various embodiments, the oxide 222 deposited over the substrate is deposited at a different deposition temperature than the deposition temperature used for depositing the oxide 211 layers in the ONON stack. The deposition temperature of oxide 222 may be between room temperature and about 600° C. Vertical slits may be subsequently etched into the substrate after depositing oxide.

The structure shown in FIG. 2A may be a structure such that previously, nitride was selectively etched from the staircase pattern to result in gaps 232. FIG. 2B shows the same structure in FIG. 2A, from a different angle, whereby gaps 232 are formed between the oxide 211 layers as a result of selectively removing nitride.

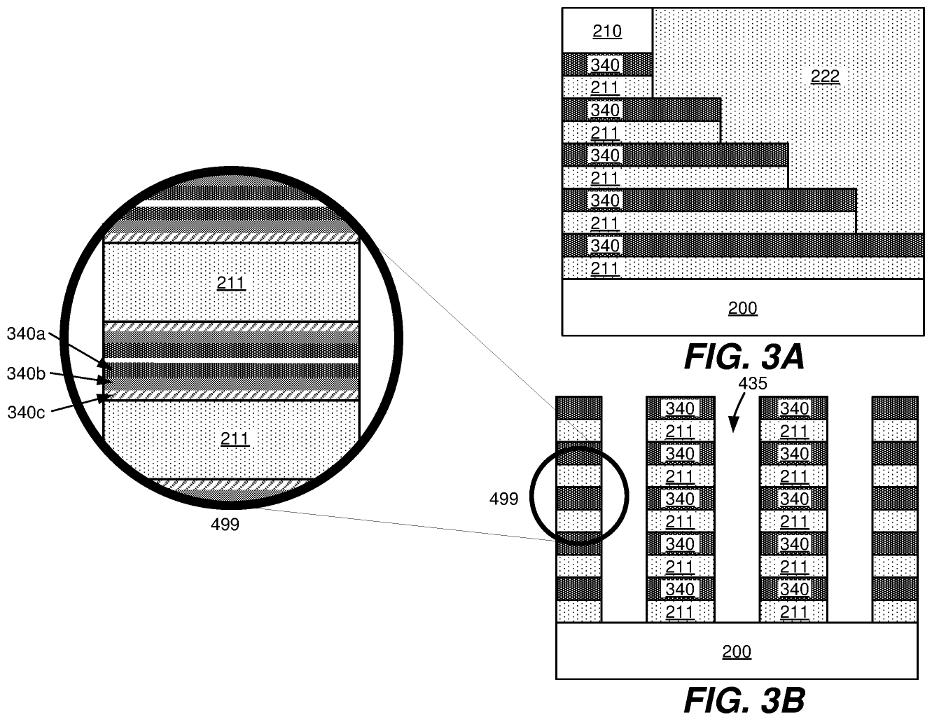

In FIG. 3A, tungsten 340 is deposited into the gaps of the substrate to form tungsten wordlines.

In the zoomed-in view 499 of the substrate surface, the tungsten 340 of FIG. 3B is shown as deposited in layers: a barrier layer 340c deposited on the exposed surfaces of oxide 211, followed by tungsten nucleation layer 340b, and bulk tungsten 340a which deposits into the remaining space of the gap. In the zoomed-in view, the bulk tungsten 340b is shown as being partially deposited just before filling the entirety of the gap. Although these three layers are depicted in FIG. 3B, it will be understood that in some embodiments, other layers may be present on the substrate.

Provided herein are methods of depositing tungsten nitride as the barrier layer, instead of titanium nitride, as using tungsten nitride as a barrier layer has advantages beyond those achievable using titanium nitride as noted above.

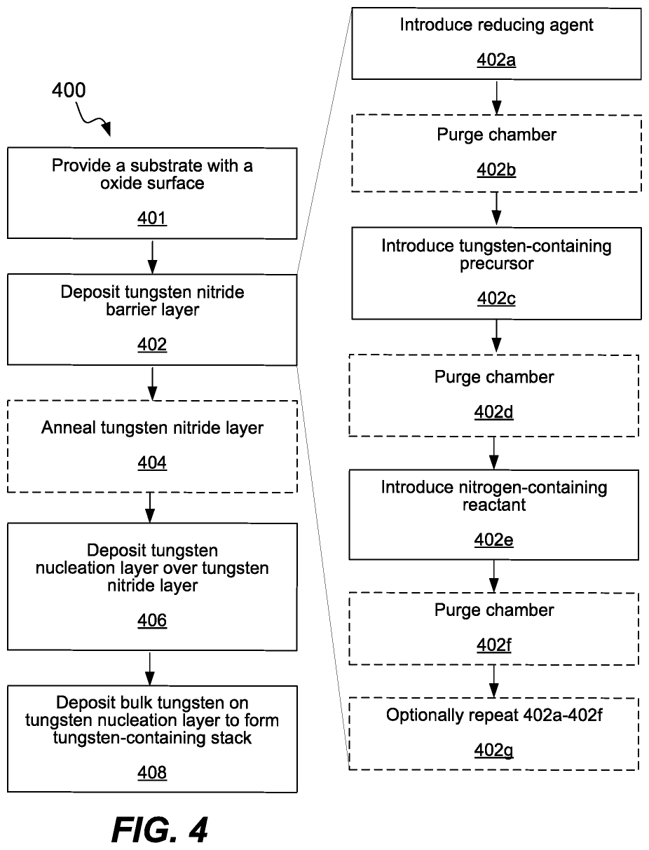

FIG. 4 is a process flow diagram 400 for a method that may be performed in accordance with certain disclosed embodiments. In operation 401, a substrate is provided to a chamber. The substrate may be placed on a pedestal in the chamber. In various embodiments, the pedestal may be a movable pedestal capable of moving vertically closer to or away from a showerhead located over the substrate on the pedestal. The substrate may include one or more features. Such a feature may have an aspect ratio of at least 10:1, at least 15:1, at least 20:1, at least 25:1, or at least 30:1. The feature size can be characterized by the feature opening size in addition to or instead of the aspect ratio. The opening may be from about 10 nm to about 100 nm wide in some embodiments. For example, in certain embodiments, the methods may be advantageously used with features having narrow openings, regardless of the aspect ratio. The methods may further be advantageously used to deposit tungsten in larger and/or smaller aspect ratio features, as well to deposit blanket or planar tungsten layers. The substrate may include a partially fabricated memory device. In various embodiments, the substrate is provided to a chamber. Exposed surfaces of features on the substrate may include oxide material, nitride material, or metal material such as aluminum or copper.

In some embodiments, the substrate includes a partially fabricated 3D NAND structure having one or more exposed oxide surfaces such as that in a staircase structure with gaps between layers of oxide. In some embodiments, the substrate includes exposed oxide surfaces, such as silicon oxide, aluminum oxide, or other oxide material.

In operation 402, a tungsten nitride barrier layer is deposited onto the substrate. In various embodiments, the tungsten nitride barrier layer is deposited on all exposed surfaces. In some embodiments, the tungsten nitride barrier layers are deposited on exposed oxide surfaces. The tungsten nitride layer referred to herein may be referred to as a barrier layer, liner layer, or interfacial layer. For example, in some embodiments, the tungsten nitride barrier layer may be referred to as a “WN liner.”

Depending on the application of the tungsten nitride barrier layer, the thickness of a tungsten nitride layer may be less than about 30 Å in thickness, such as between about 10 Å and about 15 Å. The thickness of the tungsten nitride layer deposited on two walls of a feature that are facing one another such that the deposited tungsten nitride layer occupies less than about 10% of feature opening.

The tungsten nitride layer is deposited conformally onto the substrate, using a technique such as atomic layer deposition (ALD). ALD is a technique that deposits thin layers of material using sequential self-limiting reactions. ALD processes use surface-mediated deposition reactions to deposit films on a layer-by-layer basis in cycles. As an example, an ALD cycle may include the following operations: (i) delivery/adsorption of a precursor, (ii) purging of precursor from the chamber, (iii) delivery of a second reactant and optionally ignite plasma, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc. In some cases, additional operations may occur. For example, an ALD cycle may include the following operations: (i) delivery/adsorption of a first reactant, (ii) purging of the first reactant from the chamber, (iii) delivery of a second reactant, (iv) purging from the chamber, (v) delivery of a third reactant, and (vi) purging from the chamber.

In ALD deposition of tungsten nitride films, this reaction involves reacting a reducing agent with a tungsten-containing precursor to form tungsten, and reacting the tungsten with a nitrogen-containing reactant to form tungsten nitride, with purging of the chamber performed between introducing one or more of reactant gases.

Unlike a CVD technique, ALD processes use surface-mediated deposition reactions to deposit films on a layer-by-layer basis. In one example of an ALD process, a substrate surface that includes a population of surface active sites is exposed to a gas phase distribution of a first reactant, such as a reducing agent, in a dose provided to a chamber housing a substrate. Molecules of this first reactant are adsorbed onto the substrate surface, including chemisorbed species and/or physisorbed molecules of the first reactant. It should be understood that when a compound is adsorbed onto the substrate surface as described herein, the adsorbed layer may include the compound as well as derivatives of the compound. For example, an adsorbed layer of a reducing agent may include the reducing agent as well as derivatives of the reducing agent. After a first precursor dose, the chamber is then evacuated to remove most or all of first reactant remaining in gas phase so that mostly or only the adsorbed species remain. In some implementations, the chamber may not be fully evacuated. For example, the reactor may be evacuated such that the partial pressure of the first reactant in gas phase is sufficiently low to mitigate a reaction. A second reactant, such as a tungsten-containing reactant, is introduced to the chamber so that some of these molecules react with the first reactant adsorbed on the surface. In some processes, the second reactant reacts immediately with the adsorbed first reactant. In other embodiments, the second reactant reacts only after a source of activation is applied temporally. The chamber may then be evacuated again to remove unbound second reactant molecules. A third reactant, such as a nitrogen-containing reactant, is introduced to the chamber so that some of these molecules react with the material that yielded from the reaction between the first reactant and the second reactant. The chamber may then be evacuated again to remove unbound third reactant molecules. As described above, in some embodiments the chamber may not be completely evacuated. Additional ALD cycles may be used to build film thickness.

In some embodiments, ALD involves alternating pulses between two reactants with purging in between the pulses. For example, formation of tungsten nucleation layers may be performed by alternating pulses of a reducing agent such as diborane and a tungsten-containing precursor such as tungsten hexafluoride such that a third reactant is not used.

In some implementations, the ALD methods include plasma activation. As described herein, the ALD methods and apparatuses described herein may be conformal film deposition (CFD) methods, which are described generally in U.S. patent application Ser. No. 13/084,399 (now U.S. Pat. No. 8,728,956), filed Apr. 11, 2011, and titled “PLASMA ACTIVATED CONFORMAL FILM DEPOSITION,” and in U.S. patent application Ser. No. 13/084,305, filed Apr. 11, 2011, and titled “SILICON NITRIDE FILMS AND METHODS,” which are herein incorporated by reference in their entireties.

Example operations that may be performed to deposit tungsten nitride are provided in FIG. 4 in operations 402a-402g.

In operation 402a, a reducing agent is introduced to a chamber housing the substrate. In various embodiments, the reducing agent is borane, diborane, silane, hydrogen, or any other suitable reducing agent. In various embodiments, the reducing agent is diborane. In some embodiments, the reducing agent adsorbed onto the surface of the substrate to form an adsorb-limited layer. In some embodiments, the reducing agent does not adsorb onto the entire exposed surface but at least about 70%, or at least about 80%, or at least about 90% of the substrate surface.

In operation 402b, the chamber is optionally purged to remove excess reducing agent from the process environment in the process chamber. Purging the chamber may involve flowing a purge gas or a sweep gas, which may be a carrier gas used in other operations or may be a different gas. In some embodiments, purging may involve evacuating the chamber. Example purge gases include argon, nitrogen, hydrogen, and helium. In some embodiments, operation 402b may include one or more evacuation subphases for evacuating the process chamber. Alternatively, it will be appreciated that operation 402b may be omitted in some embodiments. Operation 402b may have any suitable duration, such as between about 0 seconds and about 60 seconds, for example about 0.1 seconds.

In operation 402c, a tungsten-containing precursor is introduced to the chamber. Suitable tungsten-containing precursors include tungsten fluorides such as tungsten hexafluoride; tungsten chlorides such as tungsten pentachloride; metal-organic tungsten precursors; or other tungsten-containing gases. The tungsten-containing precursor is introduced for a duration sufficient to reacts with adsorbed reducing agent introduced in operation 402a. Although operation 402c may be performed after operation 402a in some embodiments, it will be understood that operation 402c may be performed before 402a in some embodiments such that the reducing agent is introduced to react with adsorbed tungsten-containing precursor on the substrate surface.

In operation 402d, the chamber is again optionally purged. The chamber may be purged using any of the techniques described above with respect to operation 402b.

In operation 402e, a nitrogen-containing reactant is introduced to the chamber. The nitrogen-containing reactant is introduced to react with tungsten formed on the surface of the substrate from reacting a reducing agent with a tungsten-containing precursor. While the nitrogen-containing reactant as described in this example as being introduced after formation of tungsten using a reducing agent and a tungsten-containing precursor, it will be understood that in some embodiments, the nitrogen-containing precursor may be introduced before forming tungsten such that operations 402a, operations 402c, and operation 402e may be performed in any suitable order.

A nitrogen-containing reactant is a reactant or mixture of reactants that includes at least one nitrogen, for example, ammonia, hydrazine, amines (amines bearing carbon) such as methylamine, dimethylamine, ethylamine, isopropylamine, t-butylamine, di-t-butylamine, cyclopropylamine, sec-butylamine, cyclobutylamine, isoamylamine, 2-methylbutan-2-amine, trimethylamine, diisopropylamine, diethylisopropylamine, di-t-butylhydrazine, as well as aromatic containing amines such as anilines, pyridines, and benzylamines Amines may be primary, secondary, tertiary, or quaternary (for example, tetraalkylammonium compounds). A nitrogen-containing reactant can contain heteroatoms other than nitrogen, for example, hydroxylamine, t-butyloxycarbonyl amine, and N-t-butyl hydroxylamine are nitrogen-containing reactants. Example nitrogen-containing reactants include nitrogen gas, ammonia, and amines.

In various embodiments, the nitrogen-containing reactant is nitrogen gas. In various embodiments, the nitrogen-containing reactant is ammonia gas. Nitrogen-containing reactants may be co-flowed with one or more carrier gases, such as argon gas. Accordingly, in some embodiments, the nitrogen-containing reactor introduced in operation 402e includes a mixture of nitrogen gas and hydrogen gas.

In operation 402f, the chamber is optionally purged to remove excess byproducts or gases. This operation may be performed using any of the gases or techniques described above with respect to operation 402b.

One or more of the gases introduced in any of operations 402a-402f may be delivered using a carrier gas, such as hydrogen or helium gas, which may, in some embodiments, be diverted prior to delivery to the showerhead.

In operation 402g operations 402a-402 are optionally repeated in cycles to deposit the tungsten nitride barrier layer to a desired thickness.

Operations performed with respect to operation 402 may be performed using a chamber pressure between about 3 Torr and about 90 Torr. In some embodiments, gases are delivered without a carrier gas. In some embodiments where processes gases are delivered without a carrier gas, the partial pressure of the process gases is between about 3 Torr and about 90 Torr. In some embodiments, gases are delivered with a carrier gas such as argon.

Operations performed with respect to operation 402 may be performed at a pedestal temperature for which the pedestal holding the substrate may be set to of between about 1 Torr and about 60 Torr. In some embodiments, the deposition process is a thermal process such that no plasma is ignited during either of the exposing of the substrate to the tungsten-containing precursor or exposing of the substrate to the reactant. In various embodiments, a purge gas is flowed between the exposures to expunge excess reactant molecules from the chamber.

In operation 404, the tungsten nitride layer is optionally annealed. In various embodiments, the annealing is performed for a duration sufficient to convert between about 5% and about 100% of the exposed surface of the tungsten nitride layer to tungsten metal. For a tungsten nitride layer that is formed on a horizontal surface, the top 5% to 100% of the tungsten nitride layer is converted to tungsten. In some cases, “conversion” may not occur but nitrogen may be degassed from the surface of the tungsten nitride layer to yield a tungsten surface. In some cases, trace amounts of nitrogen may remain on the surface of the tungsten but less than about 95% to less than about 1% or about 0% of the composition of the surface of the tungsten nitride layer includes nitrogen.

Annealing is performed at a temperature between about 500° C. and about 800° C. In some embodiments, annealing is performed by raising the temperature of the pedestal. In some embodiments, a gas is flowed to the substrate during this operation to stabilize the temperature. Example gases include hydrogen, argon, helium, nitrogen, ammonia, and combinations thereof.

In operation 406, a tungsten nucleation layer is deposited over the tungsten nitride layer. In some embodiments, the tungsten nucleation layer is deposited directly on the tungsten nitride layer. In some embodiments, after operation 406, the substrate includes a tungsten nucleation layer deposited adjacent to the tungsten nitride barrier layer. In some embodiments, the tungsten nucleation layer is deposited conformally over the substrate. The thickness of the tungsten nucleation layer may be between about 10 Å and about 30 Å.

The tungsten nucleation layer may be deposited by ALD, such as by using alternating pulses of a tungsten-containing precursor and reducing agent. For example, the tungsten nucleation layer may be deposited using cycles, each cycle including a pulse of tungsten hexafluoride, a purge, a pulse of diborane, and a second purge.

In some embodiments, if the tungsten nitride barrier layer was annealed prior to deposition of a tungsten nucleation layer, annealing may modify, convert, or degas the surface of the tungsten nitride layer in such way that most of the surface includes tungsten, and tungsten growth during tungsten nucleation layer deposition can be advantageous and result in low resistivity tungsten.

In some cases, the tungsten nucleation layer may have a thickness between about 5 and about 30% thickness of the overall tungsten film deposited in a feature. That is, after tungsten nucleation is deposited, the remaining feature opening size between surfaces of the tungsten nucleation layer across a feature may be more than half of the original feature opening size, less than half the original feature opening size, or less than about 30%, or about 10%, or about 0%, or 0% of the original feature opening size. In some embodiments, such as, but not limited to, 3D NAND tungsten bulk deposition, the opening may be more than half of the original feature opening size.

In various embodiments, operation 406 is performed at a temperature between about 100° C. and about 350° C. In some embodiments, the temperature may be less than about 150° C.

In some embodiments, operation 406 is performed at a chamber pressure between about 1 Torr and about 60 Torr.

In some embodiments, operation 406 is optional such that bulk tungsten in operation 408 is deposited directly on the tungsten nitride barrier layer.

In operation 408, bulk tungsten is deposited over the tungsten nucleation layer to fill the feature. In some embodiments, bulk tungsten is deposited directly on the tungsten nucleation layer. In some embodiments, after operation 408, the substrate includes a stack having bulk tungsten deposited on a tungsten nucleation layer deposited adjacent to the tungsten nitride barrier layer. In some features, sidewalls may be conformally lined with the tungsten nitride barrier layer, the surface of which is conformally lined with a tungsten nucleation layer, followed by fill of the rest of the feature with bulk tungsten.

Bulk tungsten deposition may be performed by chemical vapor deposition (CVD). In some embodiments, bulk tungsten deposition is performed by co-flowing nitrogen and tungsten hexafluoride gas.

In various embodiments, operation 408 is performed at a temperature between about 100° C. and about 500° C., or between about 150° C., or about 200° C. and about 500° C. In some embodiments, operation 408 is performed at a chamber pressure between about 3 Torr and about 90 Torr.

In some embodiments, operations 404 and 406 are performed on different pedestals on different stations within the same tool under vacuum such that operations 404 and 406 can be performed at different temperatures while a substrate can be quickly moved between the two stations to perform the operations without breaking vacuum.

In various implementations, operations 402, 406, and 408 may be performed in the same tool, or in different modules or stations of the same tool, such that operations 402, 406, and 408 are performed without breaking vacuum. Likewise, operation 404 may also be performed in conjunction with any one or more of operations 402, 406, and 408 without breaking vacuum.

In some embodiments, at least one or more of operations 402, 406, and 408 are performed in an apparatus having a particular configuration such that high partial pressure flow of gases can be distributed to the process chamber. Depending on the particular application, gas flows for depositing any one or more of the tungsten nitride barrier layer, tungsten nucleation layer, and bulk tungsten may have a partial pressure in the chamber of between about 3 Torr and about 90 Torr. In some embodiments, partial pressure is increased by moving a movable pedestal to a raised position in the process chamber to reduce the processing volume between the substrate and the showerhead to allow the substrate to be exposed to a higher partial pressure of the gas. For example, the shortest dimension in the gap between the surface of the showerhead and the surface of the pedestal may be between about 0.25 inches or less.

Although embodiments described herein are related to applications for 3D NAND fabrication, it will be understood that certain disclosed embodiments may also be related to DRAM for memory and other logic applications. Additionally, while tungsten is described herein, it will be understood that molybdenum-containing materials may be deposited using similar techniques. In some embodiments, solid molybdenum-containing precursors may be used to deposit molybdenum. In various embodiments, molybdenum is deposited over tungsten nitride barrier layers described herein.

Apparatus

Methods of the disclosed embodiments may be carried out in various types of deposition apparatuses available from various vendors. Examples of suitable apparatuses include a Lam Altus or Vector deposition system, or any of a variety of other commercially available chemical vapor deposition (CVD) or atomic layer deposition (ALD) tools. In some cases, processes may be performed on multiple depositions stations sequentially. For example, in some embodiments, tungsten nitride barrier layer is deposited in one station, tungsten nucleation layer is deposited in one station, and bulk tungsten is deposited in one station. In some embodiments, pulses of different reactant doses for depositing any one or more of tungsten nitride, tungsten nucleation, and bulk tungsten layers may be performed in different stations.

In some embodiments, an annealing operation is performed at a station that is one of two, four, five, or even more deposition stations positioned within a single deposition chamber. In some embodiments, an annealing operation is performed at a station on another chamber separate from the deposition chamber used for CVD. In various embodiments, an existing deposition station may be modified to accommodate an annealing operation.

One or more stations in a chamber may be used to perform CVD, or two or more stations may be used to perform CVD in a parallel processing. While gas and liquid precursors are described herein, in some embodiments, solid precursors are used for deposition and a suitable apparatus may be adjusted accordingly to deposit such films. For example, deposition of molybdenum may be performed using a solid molybdenum-containing precursor.

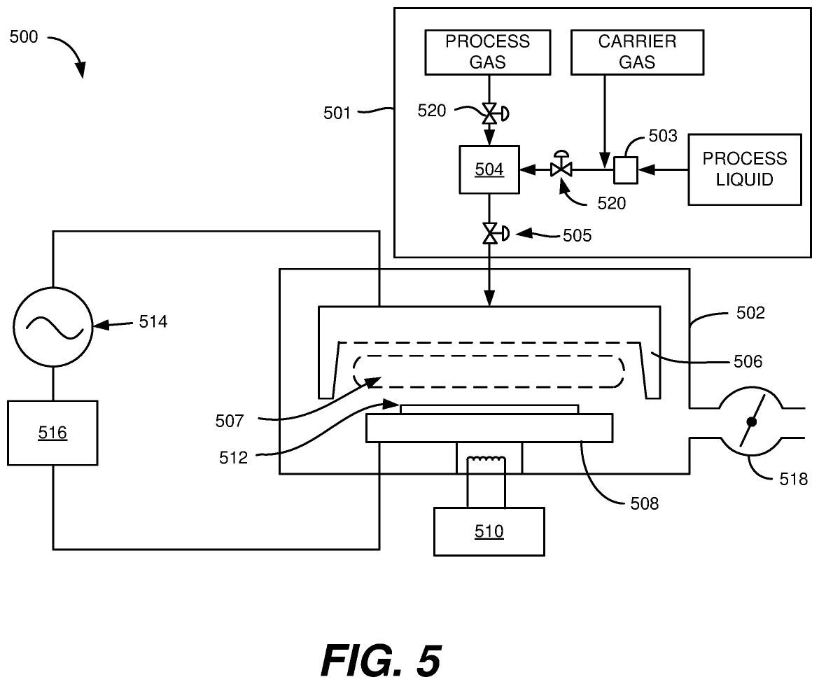

FIG. 5 schematically shows an embodiment of a process station 500 that may be used to deposit material using ALD or CVD, either of which may be plasma enhanced. For simplicity, the process station 500 is depicted as a standalone process station having a process chamber body 502. However, it will be appreciated that a plurality of process stations 500 may be included in a common process tool environment. Further, it will be appreciated that, in some embodiments, one or more hardware parameters of process station 500, including those discussed in detail below, may be adjusted programmatically by one or more computer controllers.

Process station 500 fluidly communicates with reactant delivery system 501 for delivering process gases to a distribution showerhead 506. Reactant delivery system 501 includes a mixing vessel 504 for blending and/or conditioning process gases for delivery to showerhead 506. One or more mixing vessel inlet valves 520 may control introduction of process gases to mixing vessel 504. Similarly, a showerhead inlet valve 505 may control introduction of process gases to the showerhead 506. Valve 505 may be used to allow higher pressure of gases to accumulate in mixing vessel 504 close to the showerhead 506 (that is, close in that the length of the line connecting the valve to the showerhead is shorter, such as about 3 feet, or closer) such that when valve 505 is opened, and increased amount of gases can be delivered to the showerhead 506 while maintaining its high pressure when delivered to the substrate 512. This is particularly useful for applications in which a complex structure involving gas diffusion into deep features may be performed on the substrate 512, such as for depositing tungsten into deep wordlines both vertically and laterally into feature spaces of a 3D NAND structure. Higher partial pressure of relevant reactant gases allows for an increase in uniformity of the film being deposited onto exposed surfaces of the substrate. This has improved effects over using a high volume of gas in a process station where the distance between the last valve and the showerhead is very far, because while more gas may be flowed with providing a higher overall volume of gas, the overall flow trickles slowly through the line, resulting in poor step coverage and less uniform diffusion into complex three-dimensional features. Additionally, purge operations take longer with a longer distance between the last valve and the showerhead, as purge gases must flow through this longer distance before they reach the process chamber.

Suitable distances of lines between the last valve and the showerhead vary between about 10 centimeters and about 60 centimeters in certain disclosed embodiments. Additionally, top plate valves (not shown) may also be used to allow each gas source to be individually controlled before the gases are mixed at the mixing vessel 504.

Some reactants may be stored in liquid form prior to vaporization at and subsequent delivery to the process station. For example, the embodiment of FIG. 5 includes a vaporization point 503 for vaporizing liquid reactant to be supplied to mixing vessel 504. In some embodiments, vaporization point 503 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 503 may be heat traced. In some examples, mixing vessel 504 may also be heat traced. In one non-limiting example, piping downstream of vaporization point 503 has an increasing temperature profile extending from approximately 100° C. to approximately 150° C. at mixing vessel 504.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 503. In one scenario, a liquid injector may be mounted directly to mixing vessel 504. In another scenario, a liquid injector may be mounted directly to showerhead 506.

In some embodiments, a liquid flow controller upstream of vaporization point 503 may be provided for controlling a mass flow of liquid for vaporization and delivery to process station 500. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 506 distributes process gases toward substrate 512. In the embodiment shown in FIG. 5, substrate 512 is located beneath showerhead 506, and is shown resting on a movable pedestal 508. It will be appreciated that showerhead 506 may have any suitable shape, and may have any suitable number and arrangement of ports for distributing processes gases to substrate 512. In some embodiments, the showerhead 506 may include two or more lines to distribute gases from different lines to the process chamber 502.

In some embodiments, a microvolume 507 is located beneath showerhead 506. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle may drop, the cycle time also simultaneously reduces. In certain cases, the effect of the latter is dramatic enough to improve overall throughput of the module for a given target thickness of film.

In some embodiments, movable pedestal 508 may be raised or lowered to expose substrate 512 to microvolume 507 and/or to vary a volume of microvolume 507. For example, in a substrate transfer phase, movable pedestal 508 may be lowered to allow substrate 512 to be loaded onto movable pedestal 508. During a deposition process phase, movable pedestal 508 may be raised to position substrate 512 within microvolume 507. In some embodiments, microvolume 507 may completely enclose substrate 512 as well as a portion of movable pedestal 508 to create a region of high flow impedance during a deposition process.

Optionally, movable pedestal 508 may be lowered and/or raised during portions the deposition process to modulate process pressure, reactant concentration, etc., within microvolume 507. In one scenario where process chamber body 502 remains at a base pressure during the deposition process, lowering movable pedestal 508 may allow microvolume 507 to be evacuated. Example ratios of microvolume to process chamber volume include, but are not limited to, volume ratios between 1:500 and 1:10. It will be appreciated that, in some embodiments, pedestal height may be adjusted programmatically by a suitable computer controller.

In another scenario, adjusting a height of movable pedestal 508 may allow a plasma density to be varied during plasma activation and/or treatment cycles included in the deposition process. At the conclusion of the deposition process phase, movable pedestal 508 may be lowered during another substrate transfer phase to allow removal of substrate 512 from movable pedestal 508.

While the example microvolume variations described herein refer to a height-adjustable pedestal, it will be appreciated that, in some embodiments, a position of showerhead 506 may be adjusted relative to movable pedestal 508 to vary a volume of microvolume 507. Further, it will be appreciated that a vertical position of pedestal 508 and/or showerhead 506 may be varied by any suitable mechanism within the scope of the present disclosure. In some embodiments, movable pedestal 508 may include a rotational axis for rotating an orientation of substrate 512. It will be appreciated that, in some embodiments, one or more of these example adjustments may be performed programmatically by one or more suitable computer controllers.

In some embodiments, the movable pedestal 508 may be raised such that the shortest distance between the surface of the movable pedestal 508 and the surface of the showerhead 506 is about 0.25 inches or less.

In some embodiments, the process chamber 502 is configured such that the pressure in the microvolume 507 is up to 1500 Torr or greater.

Returning to the embodiment shown in FIG. 5, showerhead 506 and pedestal 508 electrically communicate with an optional RF power supply 514 and matching network 516 for powering a plasma. In some embodiments, the plasma energy may be controlled by controlling one or more of a process station pressure, a gas concentration, an RF source power, an RF source frequency, and a plasma power pulse timing. For example, RF power supply 514 and matching network 516 may be operated at any suitable power to form a plasma having a desired composition of radical species. Examples of suitable powers are included above. Likewise, RF power supply 514 may provide RF power of any suitable frequency. In some embodiments, RF power supply 514 may be configured to control high- and low-frequency RF power sources independently of one another. Example low-frequency RF frequencies may include, but are not limited to, frequencies between 50 kHz and 500 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 508 may be temperature controlled via heater 510. Further, in some embodiments, pressure control for deposition process station 500 may be provided by butterfly valve 518. As shown in the embodiment of FIG. 5, butterfly valve 518 throttles a vacuum provided by a downstream vacuum pump (not shown). However, in some embodiments, pressure control of process station 500 may also be adjusted by varying a flow rate of one or more gases introduced to process station 500.

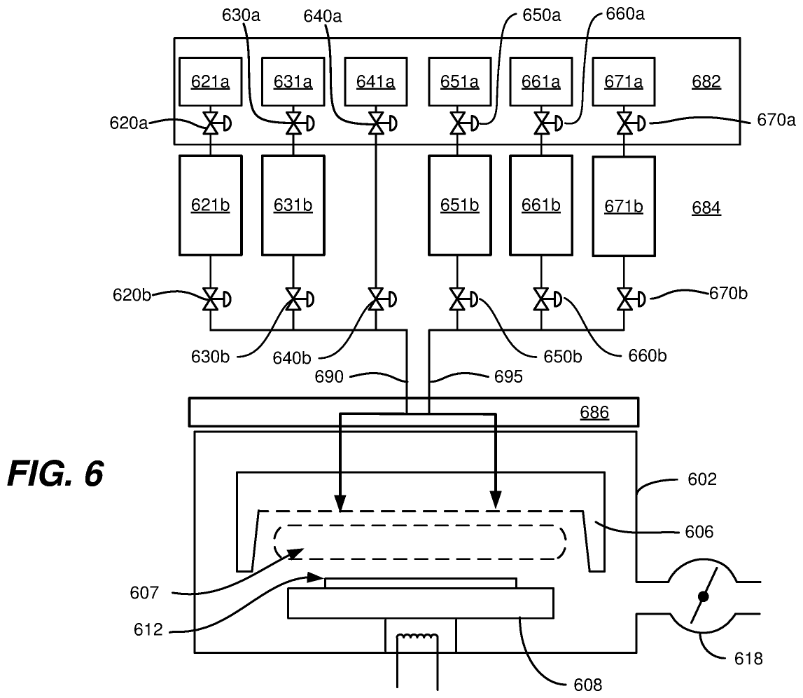

FIG. 6 shows a schematic illustration of a line diagram of gas source and line configuration for a single station of an apparatus suitable for performing certain disclosed embodiments. While only one station is depicted, it will be understood that an apparatus may include one or more of these identical, similar, or different modules for processing substrates.

In the station depicted in FIG. 6, process chamber 602 includes a showerhead 606, and a movable pedestal 608 for holding a substrate 612. Pressure control for the process chamber 602 may be provided by butterfly valve 518 to keep the process under vacuum. The microvolume 607 generated between showerhead 606 and pedestal 608 may be modulated by moving the movable pedestal 608 vertically to narrow and widen the space between the showerhead 606 and the pedestal 608, thereby changing the partial pressure of various gases in the microvolume 607.

Showerhead 606 may be a dual plenum showerhead as depicted by the two arrows, which shows that gas flows may enter the showerhead using different lines, and may also exit the showerhead using different lines, which may be performed to reduce the likelihood of gases interacting with each other in the lines. That is, in some embodiments, gases selected to be introduced in the same line may be selected such that they do not interact with each other and thus cannot result in formation of excess byproducts or deposited materials within the lines, which may contribute to the formation of defects on the substrate 612. In some embodiments, showerhead 606 may be heated. In some embodiments, showerhead 606 is both heated and is a dual-plenum showerhead.

Upstream of showerhead 606 is a manifold 686 which may be used to collect gases prior to delivery to the showerhead. In some embodiments, the manifold is configured such that gases from different lines do not interact with each other but can be separately delivered to the showerhead 606 and can also be controlled with upstream and downstream valves (not shown). Manifold 686 may be configured so that it is close in distance to the showerhead 606 to allow for high pressured volumes of gases to accumulate before a valve is released to deliver high pressure gas to the microvolume 607.

The configuration shown in FIG. 6 includes multiple gas sources, which for purposes of this example, will be referred to as being associated with a particular gas. However it will be understood that the gas sources may include any suitable gas used as a precursor or reactant for performing certain disclosed embodiments, and the configuration may be selected such that that deliver gases to one line are less likely to interact with each other or cause deposition of films than if mixed with gas sources delivered to the other line, and vice versa. It will also be understood that while three gas sources are shown as being delivered to a single line, and only two separate lines are depicted, one or more gas sources may be delivered to a single line, and two or more separate lines may all be delivered to the manifold 686 before being introduce to the showerhead 606.

Argon gas source 621a, tungsten hexafluoride gas source 631a, and nitrogen trifluoride gas source 641a are included in gas box 682 separate from top plate 684. Argon gas source 621a, tungsten hexafluoride gas source 631a, and nitrogen trifluoride gas source 641a are each delivered via its corresponding line to a line 690 to be delivered to the manifold 686.

Diborane gas source 651a, ammonia gas source 661a, and argon gas source 671a are also provided in gas box 682. Diborane gas source 651a, ammonia gas source 661a, and argon gas source 671a are each delivered via its corresponding line to a line 695 to be delivered to the manifold 686.

Flow of argon from argon gas source 621a is controlled by argon control valve 620a prior to delivery to an argon charge volume 621b such that argon can accumulate in argon charge volume 621b prior to delivery to the showerhead 606; that is, although the gas box 682 may be physically farther away from the process chamber 602, having the argon charge volume 621b in closer vicinity to the showerhead 606 and having argon outlet valve 620b to control the flow of argon from the argon charge volume 621b allows for better control and increased pressure of argon that can be delivered to the showerhead 606, and therefore delivered to the substrate 612.

Similarly, flow of tungsten hexafluoride from tungsten hexafluoride gas source 631a is controlled by tungsten hexafluoride control valve 630a prior to delivery to tungsten hexafluoride charge volume 631b such that tungsten can accumulate in tungsten hexafluoride charge volume 631b prior to delivery to the showerhead 606; that is, although the gas box 682 may be physically farther away from the process chamber 602, having the tungsten hexafluoride charge volume 631b in closer vicinity to the showerhead 606 and having tungsten hexafluoride outlet valve 630b to control the flow of tungsten hexafluoride from the tungsten hexafluoride charge volume 631b allows for better control and increased pressure of tungsten hexafluoride that can be delivered to the showerhead 606, and therefore delivered to the substrate 612.

Flow of nitrogen trifluoride from nitrogen trifluoride gas source 641a is controlled by nitrogen trifluoride control valve 640a prior to delivery. In some embodiments, nitrogen trifluoride can pass through a plasma generated prior to delivery to the process chamber 602. In some embodiments, nitrogen trifluoride is delivered from a remote plasma source. Nitrogen trifluoride outlet valve 640b may be used to control flow after nitrogen trifluoride flows through the line towards the showerhead to modulate the flow and increase pressure of the nitrogen trifluoride introduced to the showerhead 606. Nitrogen trifluoride may be used for dry clean operations.

Gases such as nitrogen trifluoride can be passed through a remote plasma generator and/or subjected to an in-situ plasma in order to generate activated etchant species (e.g., fluorine atoms, radicals). However, activated specifies tend to recombine into less active recombined etching species (e.g., fluorine molecules) and/or react with tungsten-containing materials along their diffusion paths. As such, different parts of the deposited tungsten-containing layer may be exposed to different concentrations of different etchant materials, e.g., an initial etchant, activated etchant species, and recombined etchant species.

Process gases and inert gases, such as argon, helium and others, may be supplied to a remote plasma generator from a source, which may be a storage tank. Any suitable remote plasma generator may be used for activating the etchant before introducing it into the process chamber 602. A Remote Plasma Cleaning (RPC) unit is a self-contained device generating weakly ionized plasma using a supplied etchant or suitable gas. Imbedded into the RPC unit is a high power RF generator that provides energy to the electrons in the plasma. This energy is then transferred to the neutral etchant molecules leading to temperature in the order of 2000K causing thermal dissociation of these molecules. An RPC unit may dissociate more than 60% of incoming etchant molecules because of its high RF energy and special channel geometry causing the etchant to adsorb most of this energy.

In certain embodiments, an etchant such as nitrogen trifluoride is flown from the remote plasma generator through a connecting line into the process chamber 602, where the mixture is distributed through the showerhead 606. In other embodiments, an etchant is flown into the process chamber 602 directly completely bypassing the remote plasma generator. Alternatively, the remote plasma generator may be turned off while flowing the etchant into the process chamber 602, for example, because activation of the etchant is not needed.

Flow of argon gas, tungsten hexafluoride, and nitrogen trifluoride accumulates via line 690 to manifold 686, where it is delivered to showerhead 606 separate from gases that are delivered via line 695 to prevent interactions between, for example, tungsten hexafluoride and diborane, which can form tungsten in the lines.

Flow of diborane from diborane gas source 651a is controlled by diborane control valve 650a prior to delivery of diborane to diborane charge volume 651b such that diborane can accumulate in diborane charge volume 651b prior to delivery to showerhead 606. Although gas box 682 may be physically farther away from the process chamber 602 than manifold 686, having diborane charge volume 651b in closer vicinity to showerhead 606 and having diborane outlet valve 650b to control the flow of diborane from the diborane charge volume 651b allows for better control and increased pressure of diborane that can be delivered to the showerhead 606 via manifold 686.

Flow of ammonia from ammonia gas source 661a is controlled by ammonia control valve 660a prior to delivery of ammonia to ammonia charge volume 661b, such that ammonia can accumulate in ammonia charge volume 661b prior to delivery to showerhead 606. Although gas box 682 may be physically farther away from the process chamber 602 than manifold 686, having ammonia charge volume 661b in closer vicinity to showerhead 606 and having ammonia outlet valve 660b to control the flow of ammonia from the ammonia charge volume 661b allows for better control and increased pressure of ammonia that can be delivered to the showerhead 606 via manifold 686 such that ammonia can react with tungsten-containing precursors and a reducing agent to form tungsten nitride as a barrier layer.

Flow of argon from argon gas source 671a is controlled by argon control valve 670a prior to delivery to an argon charge volume 671b such that argon can accumulate in argon charge volume 671b prior to delivery to the showerhead 606; that is, although the gas box 682 may be physically farther away from the process chamber 602, having the argon charge volume 671b in closer vicinity to the showerhead 606 and having argon outlet valve 670b to control the flow of argon from the argon charge volume 671b allows for better control and increased pressure of argon that can be delivered to the showerhead 606, and therefore delivered to the substrate 612.

Once gas accumulates and is pressurized in charge volumes and can be controlled via outlet valves, the flow of gases to the manifold 686 can increase, thereby increasing the volume and the pressure of gases introduced to microvolume 607. Such embodiments may be particular suitable for processing substrates for forming 3D NAND structures.

Apparatuses disclosed herein may be set a subatmospheric pressures, such as less than about 760 Torr, or less than about 600 Torr, to keep the substrate under vacuum. Some partial pressures of gases may be delivered up to about 1500 Torr to the substrate for a 300 mm wafer.

The movable pedestal combined with the charge volume, line, and manifold configuration can collectively cause introduction of gases to the microvolume having a partial pressure less than about 1 Torr to greater than about 90 Torr. For example, the partial pressure may be between less than 1 Torr for a 3 Torr chamber with diluted flow, or the partial pressure may be greater than 90 Torr for a 90 Torr chamber with pure flow (without carrier gas).

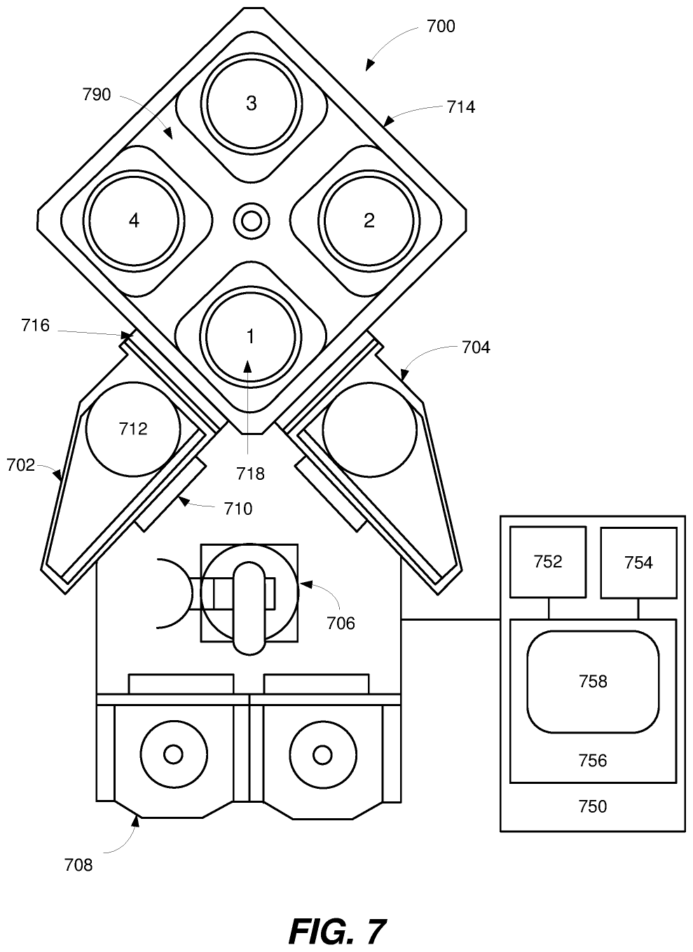

FIG. 7 shows a schematic view of an embodiment of a multi-station processing tool 700 with an inbound load lock 702 and an outbound load lock 704, either or both of which may comprise a remote plasma source. A robot 706, at atmospheric pressure, is configured to move wafers from a cassette loaded through a pod 708 into inbound load lock 702 via an atmospheric port 710. A wafer is placed by the robot 706 on a pedestal 712 in the inbound load lock 702, the atmospheric port 710 is closed, and the load lock is pumped down. Where the inbound load lock 702 comprises a remote plasma source, the wafer may be exposed to a remote plasma treatment in the load lock prior to being introduced into a processing chamber 714. Further, the wafer also may be heated in the inbound load lock 702 as well, for example, to remove moisture and adsorbed gases. Next, a chamber transport port 716 to processing chamber 714 is opened, and another robot (not shown) places the wafer into the reactor on a pedestal of a first station shown in the reactor for processing. While the embodiment depicted in FIG. 7 includes load locks, it will be appreciated that, in some embodiments, direct entry of a wafer into a process station may be provided.

The depicted processing chamber 714 comprises four process stations, numbered from 1 to 4 in the embodiment shown in FIG. 7. Each station has a heated pedestal (shown at 718 for station 1), and gas line inlets. It will be appreciated that in some embodiments, each process station may have different or multiple purposes. While the depicted processing chamber 714 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 7 also depicts an embodiment of a wafer handling system 790 for transferring wafers within processing chamber 714. In some embodiments, wafer handling system 790 may transfer wafers between various process stations and/or between a process station and a load lock. It will be appreciated that any suitable wafer handling system may be employed. Non-limiting examples include wafer carousels and wafer handling robots. FIG. 7 also depicts an embodiment of a system controller 750 employed to control process conditions and hardware states of process tool 700. System controller 750 may include one or more memory devices 756, one or more mass storage devices 754, and one or more processors 752. Processor 752 may include a CPU or computer, analog and/or digital input/output connections, stepper motor controller boards, etc.

In some embodiments, system controller 750 controls all of the activities of process tool 700. System controller 750 executes system control software 758 stored in mass storage device 754, loaded into memory device 756, and executed on processor 752. System control software 758 may include instructions for controlling the timing, mixture of gases, chamber and/or station pressure, chamber and/or station temperature, purge conditions and timing, wafer temperature, RF power levels, RF frequencies, substrate, pedestal, chuck and/or susceptor position, and other parameters of a particular process performed by process tool 700. System control software 758 may be configured in any suitable way. For example, various process tool component subroutines or control objects may be written to control operation of the process tool components necessary to carry out various process tool processes in accordance with the disclosed methods. System control software 758 may be coded in any suitable computer readable programming language.

In some embodiments, system control software 758 may include input/output control (IOC) sequencing instructions for controlling the various parameters described above. For example, each phase of a PEALD process may include one or more instructions for execution by system controller 750. The instructions for setting process conditions for a PEALD process phase may be included in a corresponding PEALD recipe phase. In some embodiments, the PEALD recipe phases may be sequentially arranged, so that all instructions for a PEALD process phase are executed concurrently with that process phase.

Other computer software and/or programs stored on mass storage device 754 and/or memory device 756 associated with system controller 750 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 718 and to control the spacing between the substrate and other parts of process tool 700.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some embodiments, there may be a user interface associated with system controller 750. The user interface may include a display screen, graphical software displays of the apparatus and/or process conditions, and user input devices such as pointing devices, keyboards, touch screens, microphones, etc.

In some embodiments, parameters adjusted by system controller 750 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 750 from various process tool sensors. The signals for controlling the process may be output on the analog and digital output connections of process tool 700. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed embodiments. Example deposition apparatuses include, but are not limited to, apparatus from the ALTUS® product family, the VECTOR® product family, and/or the SPEED® product family, each available from Lam Research Corp., of Fremont, Calif., or any of a variety of other commercially available processing systems. Two or more of the stations may perform the same functions. Similarly, two or more stations may perform different functions. Each station can be designed/configured to perform a particular function/method as desired.

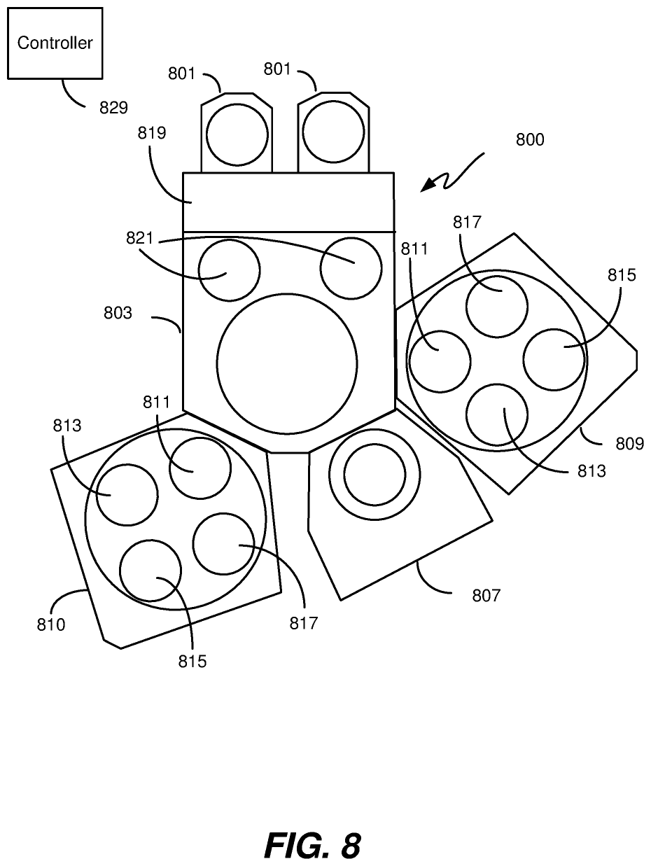

FIG. 8 is a block diagram of a processing system suitable for conducting thin film deposition processes in accordance with certain embodiments. The system 800 includes a transfer module 803. The transfer module 803 provides a clean, pressurized environment to minimize risk of contamination of substrates being processed as they are moved between various reactor modules. Mounted on the transfer module 803 are two multi-station reactors 809 and 810, each capable of performing atomic layer deposition (ALD) and/or chemical vapor deposition (CVD) according to certain embodiments. Reactors 809 and 810 may include multiple stations 811, 813, 815, and 817 that may sequentially or non-sequentially perform operations in accordance with disclosed embodiments. The stations may include a heated pedestal or substrate support, one or more gas inlets or showerhead or dispersion plate.

Also mounted on the transfer module 803 may be one or more single or multi-station modules 807 capable of performing plasma or chemical (non-plasma) pre-cleans, or any other processes described in relation to the disclosed methods. The module 807 may in some cases be used for various treatments to, for example, prepare a substrate for a deposition process. The module 807 may also be designed/configured to perform various other processes such as etching or polishing. The system 800 also includes one or more wafer source modules 801, where wafers are stored before and after processing. An atmospheric robot (not shown) in the atmospheric transfer chamber 819 may first remove wafers from the source modules 801 to loadlocks 821. A wafer transfer device (generally a robot arm unit) in the transfer module 803 moves the wafers from loadlocks 821 to and among the modules mounted on the transfer module 803.

In various embodiments, a system controller 829 is employed to control process conditions during deposition. The controller 829 will typically include one or more memory devices and one or more processors. A processor may include a CPU or computer, analog and/or digital input/output connections, stepper motor controller boards, etc.

The controller 829 may control all of the activities of the deposition apparatus. The system controller 829 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 829 may be employed in some embodiments.

Typically there will be a user interface associated with the controller 829. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 829. The signals for controlling the process are output on the analog and digital output connections of the deposition apparatus 800.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller 829 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 829, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### EXPERIMENTAL

### Experiment 1

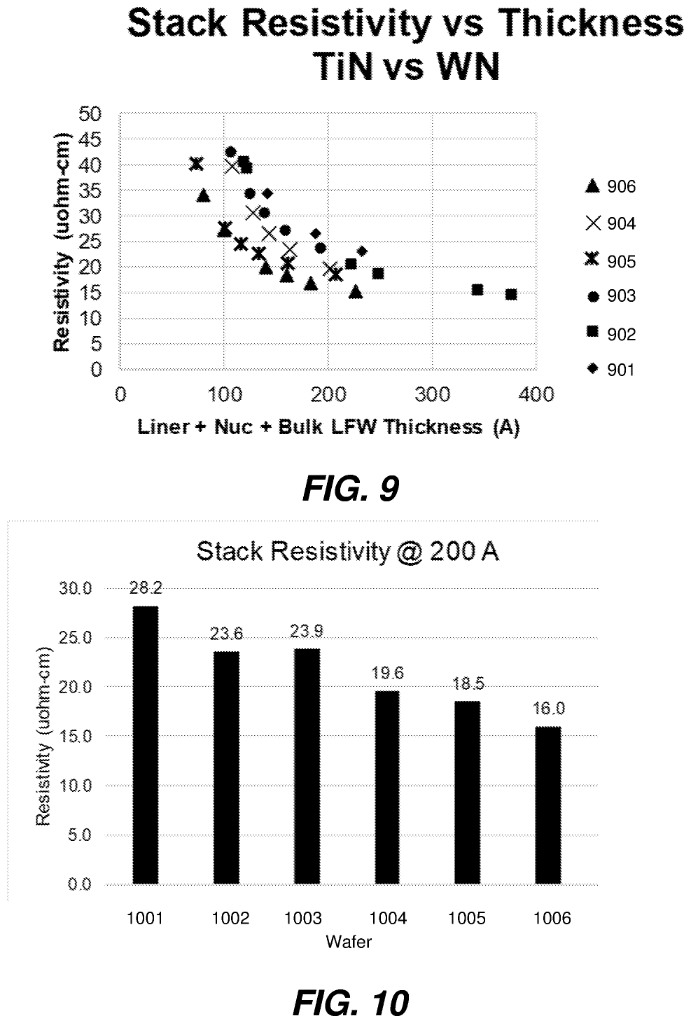

An experiment was conducted for six substrates. The substrates and their corresponding stacks and the reference numbers referred to in FIG. 9 are provided in Table 1.

TABLE 1
Tungsten Stacks in FIG. 9

| Ref # | Process | Barrier Layer | W Nucleation Layer | Bulk W |
|---|---|---|---|---|
| 901 | A | 30 Å TiN | ALD using WF₆ & B₂H₆ | CVD using WF₆ & N₂/H₂ |
| 902 | B | 30 Å TiN | ALD using WF₆ & B₂H₆ | CVD using WF₆/N₂ & H₂ |
| 903 | C | 30 Å WN | ALD using WF₆ & B₂H₆ | CVD using WF₆ & N₂/H₂ |
| 904 | D | 30 Å WN | ALD using WF₆ & B₂H₆ | CVD using WF₆/N₂ & H₂ |
| 905 | E | 10 Å WN | ALD using WF₆ & B₂H₆ | CVD using WF₆ & N₂/H₂ |
| 906 | F | 10 Å WN | ALD using WF₆ & B₂H₆ | CVD using WF₆/N₂ & H₂ |

As shown in the FIG. 9, at a given axis (such as when overall thickness is about 100 Å, or when overall thickness is about 150 Å, etc.), 903 and 904 stacks generally have lower resistivity than 901 or 902. Further, at further reduced thicknesses of tungsten nitride in 905 and 906, overall resistivity of the stack is further reduced. These results suggest that tungsten nitride is an excellent and viable solution to replacing titanium nitride as a barrier layer as it can reduce resistivity of the stack, and further that even thinner layers of tungsten nitride of about 10 Å may be used to further reduce the overall resistivity.

### Experiment 2

An experiment was conducted for the six substrates from Experiment 1 with comparison data at a tungsten thickness of 200 Å. The substrates and their corresponding stacks and the reference numbers referred to in FIG. 10 are provided in Table 2. The projected stack resistivity at 200A for substrates deposited using each of the processes described above with respect to Table 1 are provided.

TABLE 2
Resistivity for 200 Å Stacks

| | | Barrier | Resistivity @ | Resistivity Reduction |
|---|---|---|---|---|
| Ref # | Process | Layer | 200 Å | relative to Process A |
| 1001 | A | 30 Å TiN | 28.2 | 0% |
| 1002 | B | 30 Å TiN | 23.6 | −17% |
| 1003 | C | 30 Å WN | 23.9 | −15% |
| 1004 | D | 30 Å WN | 19.6 | −31% |
| 1005 | E | 10 Å WN | 18.5 | −34% |
| 1006 | F | 10 Å WN | 16.0 | −43% |

As shown in FIG. 10, reference number 1001 which included titanium nitride as the barrier layer showed overall higher stack resistivity than wafers with tungsten nitride barrier layers. Wafers with 10A tungsten nitride barrier layers exhibited the lowest resistivity, and the greatest resistivity reduction. It is noted that the difference between Process A and Process B is in the deposition of bulk tungsten; these results suggest forming bulk tungsten by ALD using WF₆/N₂ and H₂ can have reduced resistivity compared to that of bulk tungsten deposited by WF₆ and H₂/N₂, but that overall, by using tungsten nitride, the resistivity can be substantially reduced by over 30%.

### Experiment 3

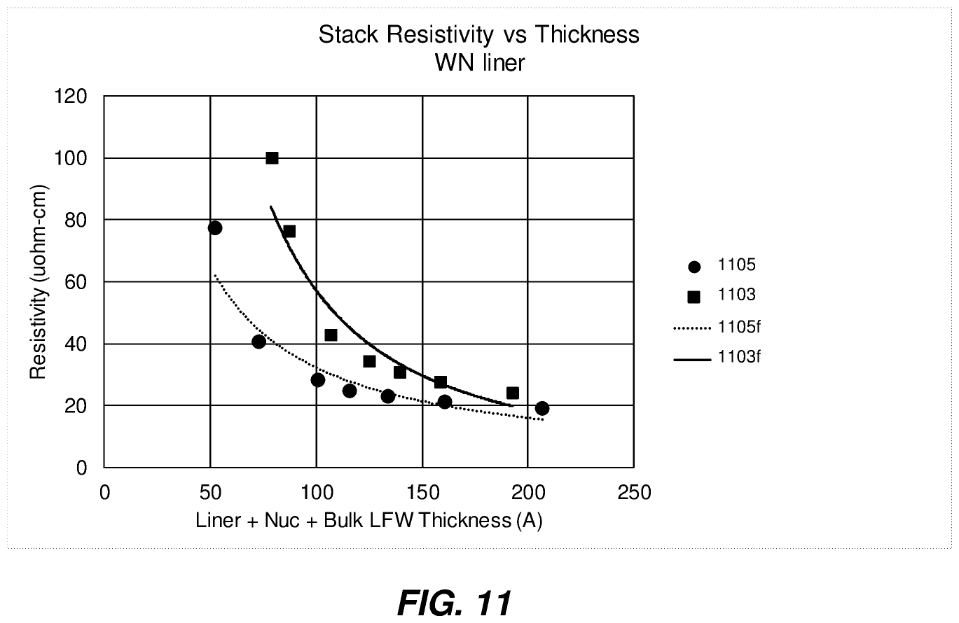

An experiment was conducted for two substrates. The substrates and their corresponding stacks and the reference numbers referred to in FIG. 11 are provided in Table 3. The projected stack resistivity is provided for substrates deposited using Processes C and E with respect to Table 1 above.

TABLE 3
Resistivity Comparison Based on WN Liner Thickness

| Ref # | Process | Barrier Layer |
|---|---|---|
| 1103 | C | 30 Å WN |
| 1105 | E | 10 Å WN |

As shown in FIG. 11, reference number 1105 which included a 10 Å WN barrier layer had consistently lower stack resistivity than reference number 1103 which included a 30 Å WN barrier layer. Fit 1105f is depicted to show the general trend of data plots in reference number 1105; likewise, fit 1103f is depicted to show the general trend of data plots for reference number 1103. In general, fit 1105f has lower stack resistivity, although the difference in stack resistivity shrinks as the thickness of the overall stack increases. These results suggest that a WN liners having a thickness of about 10 Å exhibits reduced resistivity and better results than a thicker WN liner layer.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of processing semiconductor substrates, the method comprising:
providing a semiconductor substrate;
depositing a tungsten nitride layer on the semiconductor substrate, the tungsten nitride layer having a thickness less than about 30 Å;
depositing a tungsten nucleation layer over the tungsten nitride layer; and
depositing bulk tungsten over the tungsten nucleation layer and the tungsten nitride layer.

2. The method of claim 1, wherein the tungsten nucleation layer and the bulk tungsten are deposited over the tungsten nitride layer without annealing the tungsten nitride layer.

3. The method of claim 2, wherein depositing the tungsten nitride layer further comprises annealing the tungsten nitride layer prior to depositing additional tungsten over the tungsten nitride layer.

4. The method of claim 1, wherein the depositing the tungsten nitride layer, the depositing the tungsten nucleation layer, and the depositing the bulk tungsten are performed without breaking vacuum.

5. The method of claim 3, wherein the bulk tungsten is deposited directly on the tungsten nitride layer.

6. An apparatus for processing semiconductor substrates, the apparatus comprising:
at least one processing station, the at least one processing station comprising a process chamber, the process chamber comprising a showerhead and a pedestal for holding a semiconductor substrate;
one or more gas sources;
one or more gas inlets configured to deliver gas from the one or more gas sources to one or more corresponding charge volumes; and
at least one outlet valve between the one or more corresponding charge volumes and the showerhead for controlling flow of gases from a manifold to the showerhead,
wherein a distance between one of the one or more corresponding charge volumes and the showerhead is between about 10 cm and about 60 cm.

7. The apparatus of claim 6, wherein the pedestal is movable between raised and lowered positions.

8. The apparatus of claim 6, wherein the showerhead comprises a dual-plenum showerhead.

9. The apparatus of claim 6, wherein the one or more corresponding charge volumes are configured to deliver the gas to a manifold.

10. The apparatus of claim 6, wherein the one or more corresponding charge volumes are configured to pressurize gases from the one or more gas sources by closing the at least one outlet valve downstream of the one or more corresponding charge volumes prior to delivering gas to the showerhead.

11. The method of claim 4, wherein the depositing the tungsten nitride layer, the depositing the tungsten nucleation layer, and the depositing the bulk tungsten are performed in the same chamber.

12. The method of claim 1, further comprising annealing the semiconductor substrate at a temperature between about 500° C. and about 800° C.

13. The method of claim 12, wherein the semiconductor substrate is annealed after depositing the tungsten nitride layer and before depositing the tungsten nucleation layer.

14. The method of claim 12, wherein the semiconductor substrate is annealed after depositing the bulk tungsten.

15. The method of claim 12, wherein the temperature is less than a temperature at which tungsten nitride decomposes.

16. The method of claim 1, wherein the tungsten nitride layer is deposited on a surface of the semiconductor substrate, the surface comprising oxide.

17. The method of claim 16, wherein the oxide is selected from the group consisting of silicon oxide and aluminum oxide.

18. The method of claim 1, wherein the tungsten nitride layer is deposited on a partially fabricated semiconductor substrate for forming a 3D NAND structure.

19. The method of claim 1, wherein the tungsten nitride layer is deposited on a partially fabricated semiconductor substrate for forming a tungsten word line.
